(19) United States
(12) Patent Application Publication
(10) Pub. No.: US 2025/0162431 A1
(43) Pub. Date: May 22, 2025

(54) ELECTRICAL VEHICLE INTERNAL GENERATOR

(71) Applicant: AF/GS EV IN-GEN Patent JV, Naperville, IL (US)

(72) Inventors: Ahmed Naveed Fazil, Prospect, IL (US); Glenn Seiden, Chicago, IL (US)

(21) Appl. No.: 18/948,169

(22) Filed: Nov. 14, 2024

Related U.S. Application Data
(60) Provisional application No. 63/600,539, filed on Nov. 17, 2023.

(51) Int. Cl. B60L 50/61; B60L 50/52; B60L 58/13; H02J 7/00; H02J 7/14

(52) U.S. Cl. CPC B60L 50/61; B60L 50/52; B60L 58/13; H02J 7/00309; H02J 7/1492

(57) ABSTRACT

An apparatus of the subject technology comprises a battery pack configured to provide power for an electrical vehicle (EV), and a motor powered by a fuel supplied by a fuel tank and configured to provide mechanical power for one or more electrical machines. The one or more electrical machines are configured to generate a direct current (DC) voltage for keeping the battery pack fully charged, and the battery pack, the motor and the one or more electrical machines are enclosed in a battery-system enclosure.

### CROSS REFERENCE TO RELATED APPLICATIONS

This present application claims the benefit of priority under 35 U.S.C. § 119(e) to U.S. Provisional Application No. 63/600,539, filed Nov. 17, 2023, the disclosure of which is hereby incorporated by reference in its entirety for all purposes.

### TECHNICAL FIELD

The present disclosure generally relates to the batteries that power electric vehicle (EVBs), and more particularly, to a power generator being housed inside the EVB casing with fuel delivered to it from the cars fuel tank.

### BACKGROUND

EVs and hybrid cars are becoming popular as serious competitors to gas-fueled cars in many countries. The primary issues facing EV owners by their vehicles include range, temperature, fires and charging time. The biggest worry people tend to have when it comes to EVs has to do with what's called “range anxiety”, the fear that the EV will run out of power before a suitable place to recharge the battery can be found. Regarding the battery temperature, EV batteries are sensitive to extreme heat and extreme cold. Extreme heat can speed up the degradation of an EV battery pack, whereas extreme cold can negatively affect the vehicle's range. Charging time can also be considered a key drawback to EVs. Whereas filling your average ICE vehicle's fuel tank with petrol takes mere minutes, charging an EV can take much longer, for example, 15 minutes to 48 hours, depending on the type of charger being used (Level-1 alternative current (AC) trickle charging using a domestic socket, Level 2 AC fast charging, or Level 3 DC rapid charging). The most important issue with charging is the lack of installed charging locations, which are even rarer in rural areas.

EV battery fires are another concern, as it becomes tricky and harder for firefighters to put out when compared to fires in ICE vehicles, and may require larger amounts of water, or even a special fire extinguisher, to be effectively quashed. Furthermore, EVs are not as green as people think or as companies claim. With their zero-emission tailpipes, EVs are almost certainly better for the environment, but that does not mean they are 100 percent carbon neutral. This is because, unless charged with renewable energy (e.g., wind or solar), using electricity generated in a power plant results in carbon dioxide (CO2) emission by the power plant. Also, the mining and manufacturing of EV batteries is an extremely dirty and carbon intensive process.

Hybrid cars, on the other hand, are new and expensive, as the technology that powers hybrid cars is still new and complex. This can make them difficult to repair and service, and parts can be expensive as well. Many drivers feel more comfortable with the simpler technology of a traditional gasoline car. As with any new technology, hybrid cars come with their own set of potential problems. One such problem is increased maintenance costs because hybrid cars have two infrastructures and motors (gasoline and electrical), thus more parts can break down and need repairs. This means that owners of hybrid cars may have to pay more for routine maintenance and breakages more often, and repair costs may be higher than owners of traditional gas-powered cars. One of the main problems that owners of hybrid cars face is that the battery life is not as long as electric cars. This means that people who own hybrid cars have to replace the battery more often, which can be expensive. Limited efficiency of the regenerative brake system is another issue with hybrid cars. The regenerative brake system is designed to recharge the battery by converting the kinetic energy of the vehicle into electrical energy while braking. But this system is not very efficient, as it only captures a small amount of the energy that is available. As a result, the battery does not get charged as much as it could, which reduces the fuel efficiency of the vehicle. Hybrid cars have less trunk space than traditional gasoline-powered cars. This is because the battery pack takes up a good amount of space in the trunk. This can be a problem if you need to transport a lot of items, since there may not be enough room to do so.

### SUMMARY

According to some embodiments, an apparatus of the subject technology comprises a battery pack configured to provide power for an EV, using a power generator, or motor powered by a fuel supplied by a fuel tank and configured to provide mechanical power for one or more electrical machines. The one or more electrical machines are configured to generate a direct current (DC) voltage for keeping the battery pack fully charged, and the battery pack, the motor and the one or more electrical machines are enclosed in a battery-system enclosure. With fuel available to the power generator from the fuel tank there would not be a need for an external charging option.

According to other embodiments, an EV of the subject technology includes a battery system consisting of a battery pack configured to provide power for a first electric motor by a second motor configured to be powered by a fuel supplied by a fuel tank and to provide mechanical power for one or more electrical machines, wherein the one or more electrical machines are configured to generate a DC voltage for keeping the battery pack fully charged. A battery-management system is configured to manage an operation of the second motor. The battery system is enclosed in a battery-system enclosure.

According to yet other embodiments, a method of the subject technology includes providing a battery pack for supplying a first DC voltage to a traction motor of an EV, and electrically coupling the battery pack to an output of one or more electrical machines to generate a second DC voltage for keeping the battery pack fully charged. The method further includes mechanically coupling an ICE to the one or more electrical machines, and coupling a fuel tank including a liquid fuel and positioned inside the EV to the ICE.

### BRIEF DESCRIPTION OF THE DRAWINGS

The accompanying drawings, which are included to provide further understanding and are incorporated in and constitute a part of this specification, illustrate disclosed embodiments and together with the description serve to explain the principles of the disclosed embodiments.

FIG. 1 is a high-level block diagram illustrating an example of an internal generator EV (IGEV), according to some aspects of the subject technology.

FIG. 2 is a schematic diagram illustrating an example structure of an IGEV, according to some aspects of the subject technology.

FIG. 3 is a block diagram illustrating an example architecture of an EV internal generator (EVIG) system, according to some aspects of the subject technology.

FIG. 4 is a schematic diagram illustrating an example of a single-stroke engine and corresponding characteristics that can be used in the EVIG of the subject technology.

FIG. 5 is a schematic diagram illustrating an example of a single-stroke engine along with a scaled-up engine and corresponding characteristics.

FIG. 6 is a table illustrating a comparison between a characteristics vector of an example of an EVIG of the subject technology with that of a typical ICE car and a traditional EV.

FIG. 7 is a table illustrating a comparison between components of an example of an EVIG of the subject technology with that of a typical ICE car and a traditional EV.

FIG. 8 is a table illustrating a comparison between a characteristics vector of an example of an internal-generator light truck of the subject technology with a typical ICE light truck.

FIG. 9 is a table illustrating a comparison between a characteristics vector of an example of an internal-generator semi-truck battery system of the subject technology with a typical electric semi-truck battery.

FIG. 10 is a table illustrating a comparison between a characteristics vector of an example of an internal-generator heavy truck of the subject technology with a typical electrical heavy truck.

FIG. 11 is a flow diagram illustrating an example of a method of fabrication of an internal generator system for an EVIG, according to some aspects of the subject technology.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION

In the following detailed description, numerous specific details are set forth to provide a full understanding of the present disclosure. It will be apparent, however, to one ordinarily skilled in the art, that the embodiments of the present disclosure may be practiced without some of these specific details. In other instances, well-known structures and techniques have not been shown in detail so as not to obscure the disclosure.

In some aspects, the subject technology is directed to an EV internal generator. The internal generator of the subject technology consists of a battery system. The disclosed battery system includes a battery pack, an ICE, one or more electric machines (e.g., two) and a battery-management system enclosed in a battery-system enclosure. The ICE is a small (e.g., 4″×4″×18″) single-stroke ICE that provides mechanical power for the one or more electrical machines. The ICE is powered by a liquid fuel supplied by a fuel tank, which is installed in a compartment (e.g., a trunk) of the EV. The one or more electrical machines are configured to generate a DC voltage to keep the battery pack fully charged. The battery-management system is used to manage an operation of the ICE. In some embodiments, the EV can be any transportation vehicle, and is not limited to, a car, a truck, a boat, a ship, or a plane.

The battery pack provides electrical power for an electric motor (e.g., traction motor) of the EV. The battery pack does not need to be plugged into an external charger such as a super charger or any other external charger. The fuel carried within the fuel tank is the only source of power for the EV. The fuel can be a liquid fuel including, but not limited to, compressed natural gas (CNG), petrol, diesel, propane or hydrogen.

The disclosed EV, equipped with the battery system of the subject technology, does not need external engines, transmissions, oil pumps and the associated costs related to manufacturing hybrid vehicles. The disclosed EV mitigates the issues faced by the existing hybrid cars and the conventional EVs as described above in the background section.

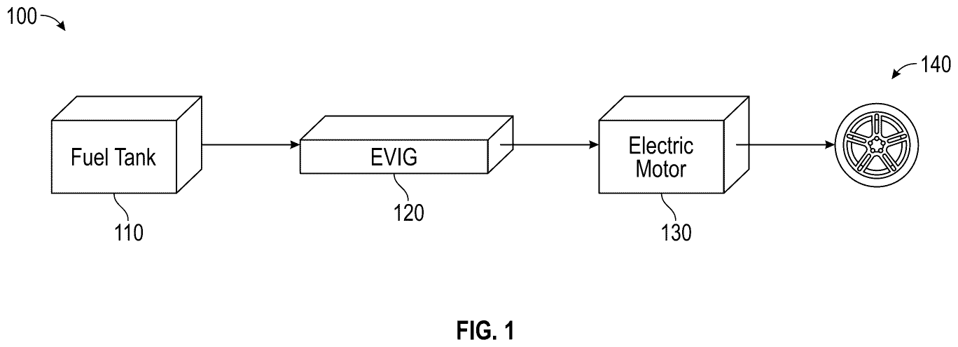

Turning now to the figures, FIG. 1 is a high-level block diagram illustrating an example of an IGEV 100, according to some aspects of the subject technology. The IGEV 100 (e.g., a car, a truck, a boat, a chip or a plane) includes a fuel tank 110, an EVIG 120, an electric motor 130 and wheels 140. The fuel tank 110 contains stored chemical energy in the form of a fuel (e.g., a liquid fuel) from a list including, but not limited to, CNG, petrol, diesel, propane or hydrogen. The fuel tank 110 may be carried inside a compartment of the IGEV 100, for example, in the trunk of a car. The EVIG 120 is a system enclosed in a battery-system enclosure that transforms the stored chemical energy into electrical energy and includes an ICE, one or two electric machines (e.g., alternators), a battery pack, a battery management system (BMS) and other components, as described in more details herein. The electric motor 130 is the traction motor of the IGEV 100 that is powered by the EVIG 120 and transforms the electric energy into mechanical energy (rotational energy) that turns the wheels 140 of the IGEV 100, which in turn converts rotational energy to movement.

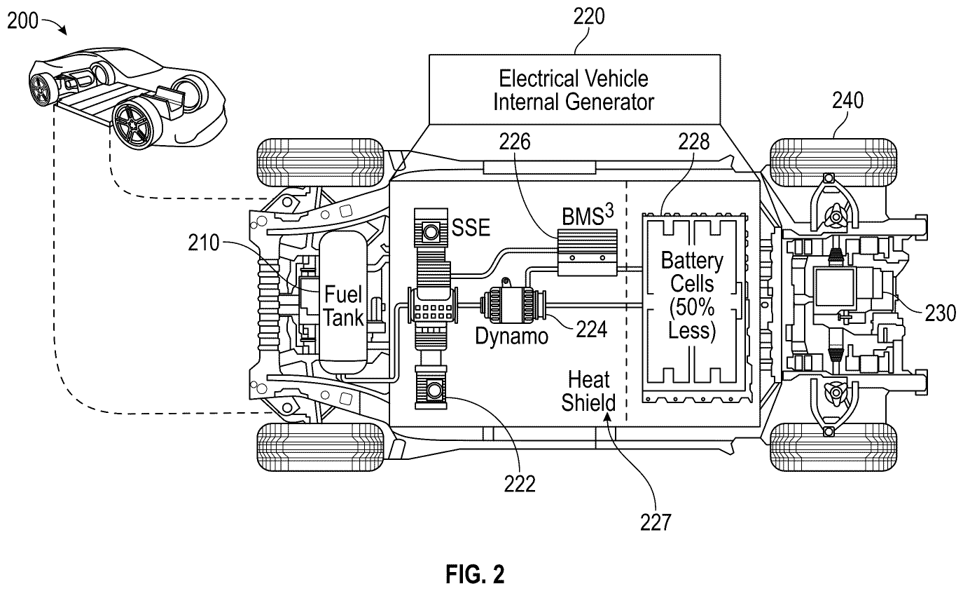

FIG. 2 is a schematic diagram illustrating an example structure of an IGEV 200, according to some aspects of the subject technology. The IGEV 200 includes a power system consisting of a fuel tank 210, an EVIG 220, an electric motor 230 and the wheels 240. The fuel tank 210 is placed in a compartment of the IGEV 200 (e.g., a trunk of a car) and includes a liquid fuel such as CNG, petrol, diesel, propane or hydrogen. The EVIG 220 includes, but is not limited to, a motor 222, one or more electric machines 224 (e.g., dynamos), a BMS 226, a heat shield 227 and a battery pack 228. The motor 222 is an ICE such as a single-stroke ICE that is fueled by the fuel tank 210. The motor 222 provides mechanical energy for the electric machine 224, which converts the mechanical energy to electrical energy for charging the battery pack 228. The electric motor 230 is a traction motor that is powered by the battery pack 228 and runs the wheels 240 that causes movement of the IGEV 200. The heat shield 227 isolates the battery 228 from the rest of the components of the EVIG 220.

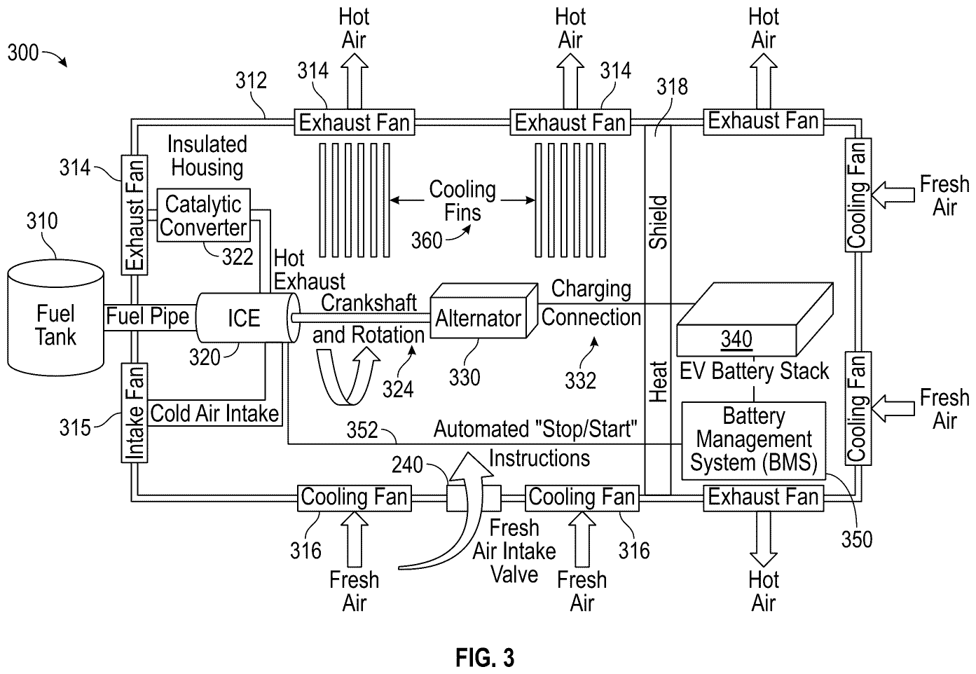

FIG. 3 is a block diagram illustrating an example architecture of an EVIG system 300, according to some aspects of the subject technology. The EVIG system 300 includes a fuel tank 310, an ICE 320 (e.g., a single-stroke engine), an alternator 330, a battery pack (stack) 340, a BMS 350, cooling fins 360, all enclosed in an insulated housing 312 (also referred to as the battery system enclosure). The insulated housing 312 has two compartments separated by a heat shield 318 that isolates the battery pack 340 and the BMS 350 from the rest of the components. The insulated housing 312 further includes exhaust fans 314, an intake fan 315, cooling fans 316 and a fresh-air intake valve 240. The intake fan 315 blows in cold air to cool the ICE 320. The host exhaust from the single-stroke ICE 320 is passed through a catalytic converter 322 and blown out via the exhaust fan 314. Other exhaust fans 314 blow out the hot air from the cooling fins 360, the battery pack 340 and the BMS 350. The cooling fans 316 blow in fresh air from the outside environment to help cool the components inside the insulated housing 312.

The ICE 320 is powered by a fuel (e.g., a liquid fuel) such as CNG or other suitable fuels stored in the fuel tank 310. The alternator 330 is mechanically coupled to the ICE 320 by a crankshaft 324, which causes rotation of an armature of the alternator 330 to generate a DC voltage for charging the battery pack 340 though the charging connection (e.g., copper wires) 332. The BMS 350 is an electronic control module such as a microcontroller or a field-programmable gate array (FPGA) that can be programmed to control operation of the ICE 320 to maintain the battery pack is always fully charged (e.g., within 98% to 100% of maximum charging capacity of the battery pack). For example, the BMS 350 can send stop/start instructions 352 to the ICE 320 to control start and stop of the ICE 320. In some implementations, the BMS 350 may also control the operations of the exhaust fans 314, the intake fan 315 and the cooling fans 316.

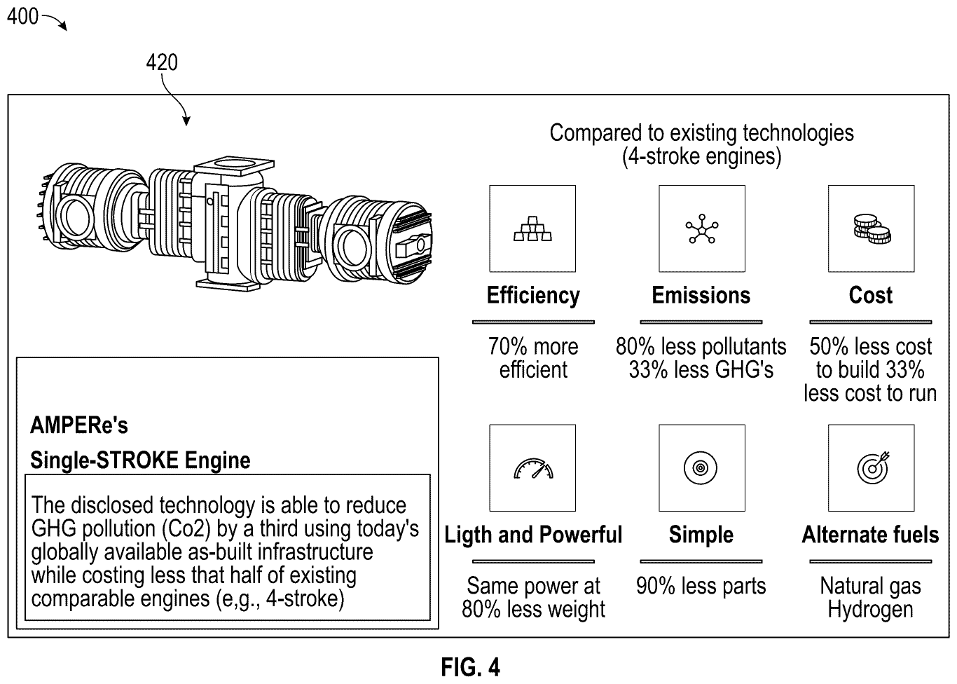

FIG. 4 is a schematic diagram 400 illustrating an example of a single-stroke engine 420 and corresponding characteristics that can be used in the EVIG of the subject technology. The single-stroke engine 420 (e.g., an ICE) is the same as the ICE 320 used in the EVIG system 300 of FIG. 3. The disclosed technology is able to reduce GHG pollution (CO2) by a third using today's globally available as-built infrastructure while costing less than half of existing comparable engines (e.g., four-stroke). More specifically, in comparison with a four-stroke engine commonly used in gas and hybrid cars, the single-stroke engine has better characteristics. For example, the single-stroke engine 420 is 70% more efficient, generates 80% less pollutants (e.g., 33% less green-house gases (GHGs)), is 50% less costly to build and 33% less costly to run. Other beneficial characteristics of the single-stroke engine 420 include having light weight and being powerful (e.g., 80% lighter with the same power), being less complex with 90% less parts and being able to use alternate fuels such as CNG, petrol, diesel, propane, hydrogen or other liquid fuels.

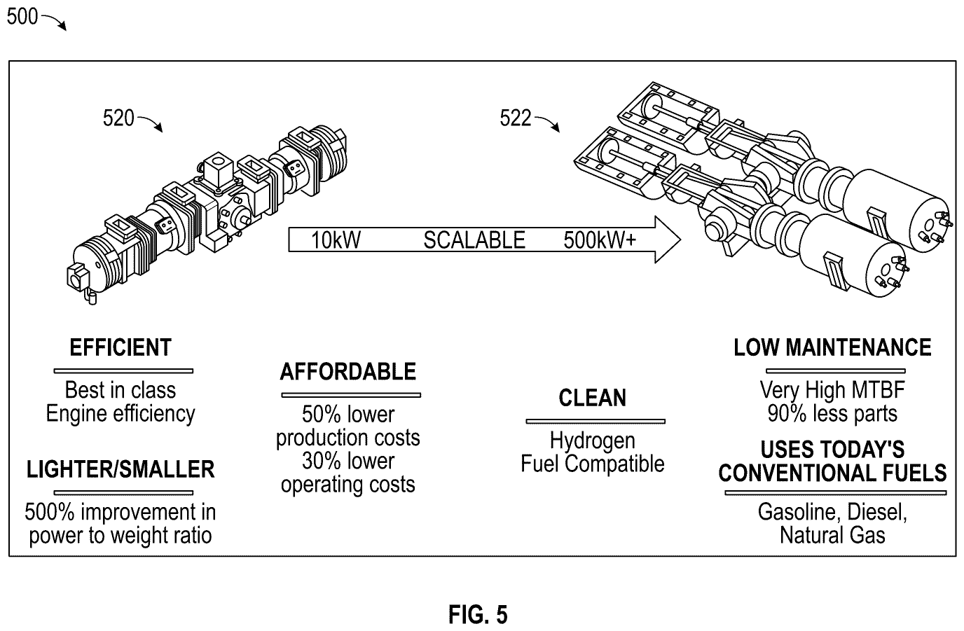

FIG. 5 is a schematic diagram 500 illustrating an example of a single-stroke engine 520, along with a scaled-up engine 522 and corresponding characteristics. The single-stroke engine 520 can be a 10 KW engine used in smaller vehicles, but can be scaled up, for example to 500 KW, for larger vehicles such as trucks, ships, and other large vehicles. The advantages and features of the single-stroke engine 520 as presented in FIG. 5 are similar to those described above with respect to FIG. 4.

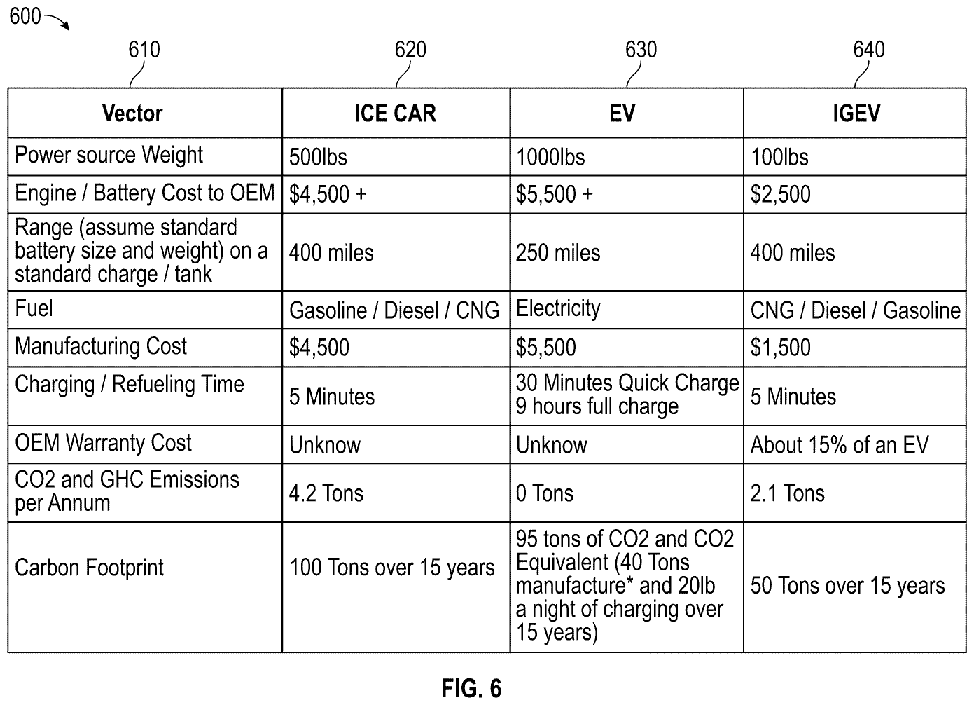

FIG. 6 is a table 600 illustrating a comparison between a characteristics vector 610 of an example of an EVIG of the subject technology with that of a typical ICE car and a traditional EV. Table 600 includes columns 620, 630 and 640 listing values of a characteristics vector 610 for an ICE car, an EV, and an EVIG, respectively. The characteristics vector 610 includes power source weight, engine/battery cost to original equipment manufacturer (OEM), fuel, manufacturing cost, charging/fueling time, OEM warranty cost, CO2 and GHG emission per annum, and carbon footprint. A review of the table 600 indicates that for almost all characteristics, the EVIG of the subject technology surpasses the ICE cars and EVs. For example, the EVIG is lighter and less expensive, has more or comparable range, is less expensive to manufacture, takes a short time to refuel and is much better in terms of carbon footprint.

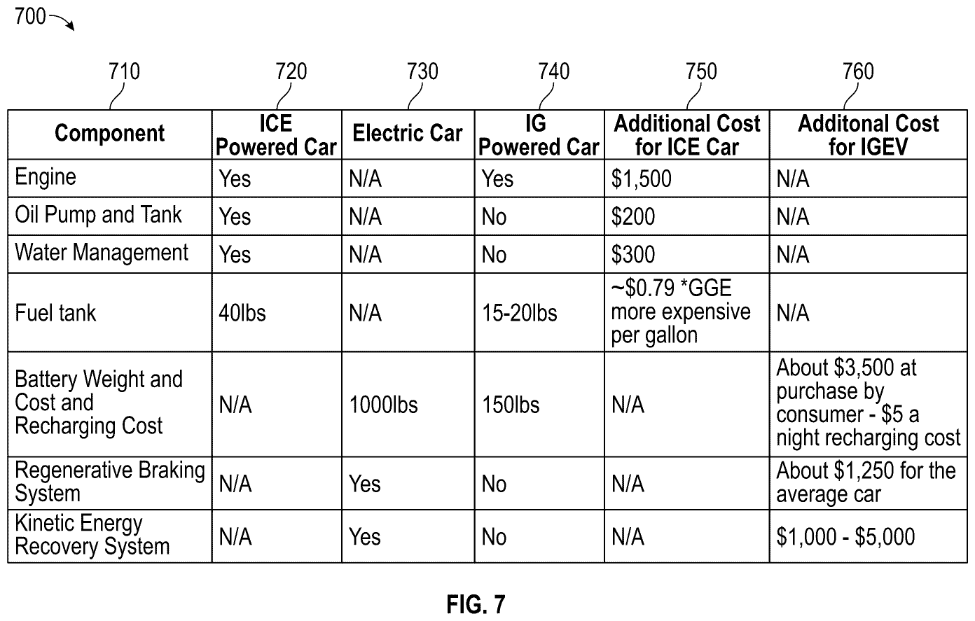

FIG. 7 is a table 700 illustrating a comparison between components 710 of an example of an EVIG of the subject technology with that of a typical ICE car and a traditional EV. Table 700 includes columns 720, 730, 740 and listing components 710 for an ICE powered car, an EV, and an EVIG, respectively, and columns 750 and 760 listing additional cost for ICE car and additional cost for EVIG. The components 710 include engine, oil pump and tank, water management, fuel tank, battery weight and cost and recharging cost, regenerative braking system and kinetic energy recovery system. A review of the table 700 indicates that the EVIG of the subject technology has less components than the ICE cars and has less battery weight compared to EVs.

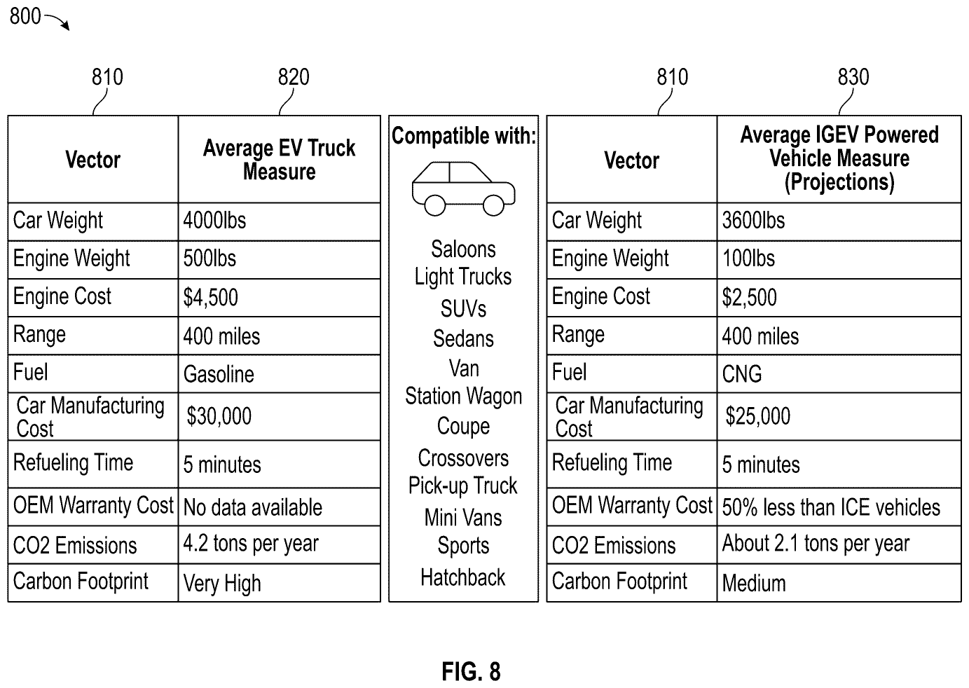

FIG. 8 is a table 800 illustrating a comparison between characteristics vectors 810 of an example of an IG light truck of the subject technology with a typical ICE light truck. Table 800 includes columns 820 and 830 listing values of a characteristics vector 810 for an ICE and an IG light truck, respectively. The characteristics vector 810 includes car weight, battery weight, battery cost, range fuel, car manufacturing cost, refueling time, OEM warranty cost, CO2 emission, and carbon footprint. A review of the table 800 indicates that for almost all characteristics, the IG light truck of the subject technology surpasses the ICE light truck.

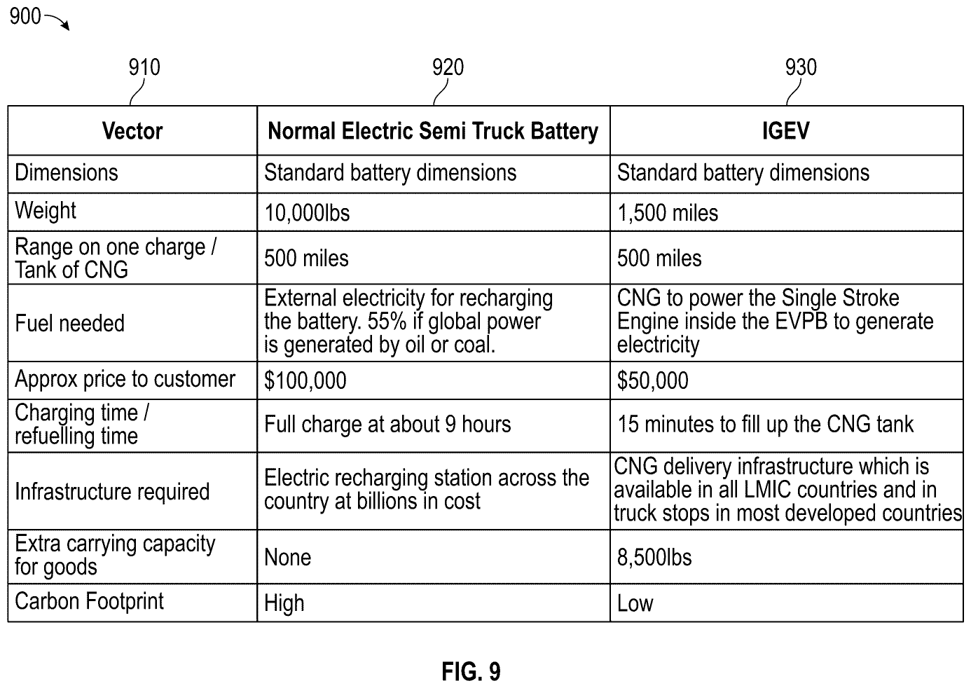

FIG. 9 is a table 900 illustrating a comparison between a characteristics vector 910 of an example of an IG semi-truck battery system of the subject technology with a typical electric semi-truck battery. Table 900 includes columns 920 and 930 listing values of the characteristics vector 910 for an ICE and an EVIG semi-truck, respectively. The characteristics vector 910 includes dimensions, weight, range on one charge/tank of CNG, fuel needed, approximate price to the customer, charging time/refueling time, infrastructure requirement, extra carrying capacity for goods and carbon footprint. A review of the table 900 indicates that for almost all characteristics, the EVIG semi-truck of the subject technology has better/comparable features compared to an ICE light truck. For example, the IG semi-truck battery system is lighter and less expensive, has a comparable range, is less expensive to the customer, takes much shorter time to refuel and is much better in terms of carbon footprint.

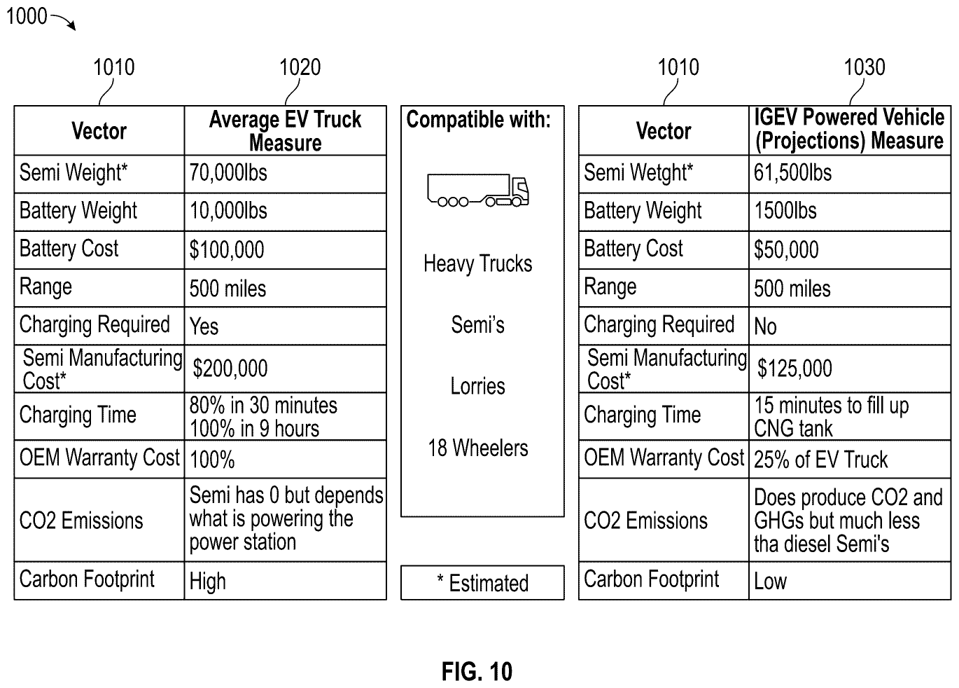

FIG. 10 is a table 1000 illustrating a comparison between a characteristics vector 1010 of an example of an IG heavy truck of the subject technology with a typical EV truck. Table 1000 includes columns 1020 and 1030 listing values of the characteristics vector 1010 for an EV and an IG heavy truck, respectively. The characteristics vector 1010 includes semi weight, battery weight, battery cost, range, charging required, semi manufacturing cost, charging time, OEM warranty cost, CO2 emission and carbon footprint. A review of the table 1000 indicates that for almost all characteristics, the IG heavy truck of the subject technology has better features compared to an EV heavy truck. For example, the IG heavy-truck battery is lighter and less expensive, has a comparable range and less OEM warranty cost, takes much shorter time to refuel and is much better in terms of carbon footprint.

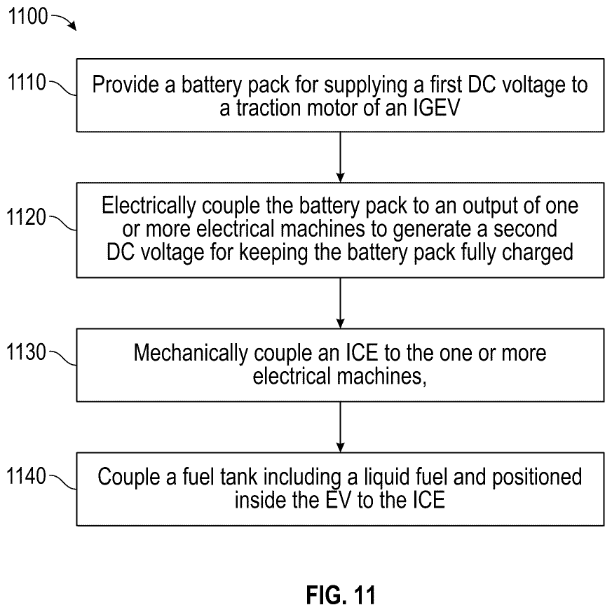

FIG. 11 is a flow diagram illustrating an example of a method 1100 of fabrication of an IG system for an EV (e.g., 200 of FIG. 2), according to some aspects of the subject technology. The method 1100 includes steps 1110, 1120, 1130 and 1140.

In step 1110, a battery pack (e.g., 228 of FIG. 2) for supplying a first DC voltage to a traction motor (e.g., 230 of FIG. 2) of an EV is provided.

In step 1120, the battery pack is electrically coupled to an output of one or more electrical machines (e.g., 224 of FIG. 2) to generate a second DC voltage for keeping the battery pack fully charged.

In step 1130, an ICE (e.g., 222 of FIG. 2) is mechanically coupled to the one or more electrical machines.

In step 1140, a fuel tank (e.g., 210 of FIG. 2) including a liquid fuel and positioned inside the EV is coupled to the ICE.

An aspect of the subject technology is directed to an apparatus including a battery pack configured to provide power for an EV and a motor powered by a fuel supplied by a fuel tank and configured to provide mechanical power for one or more electrical machines. The one or more electrical machines are configured to generate a direct current (DC) voltage for keeping the battery pack fully charged, and the battery pack, the motor and the one or more electrical machines are enclosed in a battery-system enclosure.

In some implementations, the motor comprises a single-stroke internal combustion engine (ICE).

In one or more implementations, the one or more electric machines comprise one or more alternators, wherein the DC voltage is regulated to match a nominal voltage of the battery pack.

In some implementations, the fuel comprises a liquid fuel including one of compressed natural gas (CNG), petrol, diesel, propane or hydrogen.

In one or more implementations, the fully charged battery pack comprises a level within a range of about 98 to 100 percent of a maximum allowable charge level associated with the battery pack.

In some implementations, the fuel tank is carried by the EV in a compartment inside the EV.

In one or more implementations, the battery-system enclosure further includes an internal heat shield arranged to shield a battery compartment including the battery pack from other components in the battery-system enclosure.

In some implementations, the battery-system enclosure further includes a battery-management system configured to control an operation of the motor to keep the battery pack always fully charged.

In some implementations, the battery-system enclosure further includes one or more vents configured to automatically open to allow filtered fresh air in the EVIG for cooling at a threshold speed, wherein the threshold speed is 25 mile per hour (mph).

In one or more implementations, the EV comprises one of a car, a truck, a boat, a ship, or an airplane.

In some implementations, the battery-system enclosure further includes cooling fins made of a heat conductive material.

In one or more implementations, the battery-system enclosure further includes a plurality of exhaust fans configured to remove hot air from compartments of the battery-system enclosure.

In some implementations, the battery-system enclosure further includes a plurality of cooling fans configured to blow fresh air into compartments of the battery-system enclosure.

Another aspect of the subject technology is directed to an EV including a battery system consisting of a battery pack configured to provide power for a first electric motor and a second motor configured to be powered by a fuel supplied by a fuel tank and to provide mechanical power for one or more electrical machines, wherein the one or more electrical machines are configured to generate a DC voltage for keeping the battery pack fully charged. A battery-management system is configured to manage an operation of the second motor. The battery system is enclosed in a battery-system enclosure.

In some implementations, the battery-management system is configured to manage an operation of the second motor to always keep the battery pack fully charged.

In one or more implementations, the first electric motor comprises a traction motor, and the second motor comprises a single-stroke ICE.

In some implementations, the fuel tank contains a liquid fuel comprising one of CNG, petrol, diesel, propane or hydrogen.

In one or more implementations, the battery-system enclosure further includes cooling fins made of a heat conductive material.

In some implementations, the battery-system enclosure further includes a plurality of exhaust fans configured to remove hot air from compartments of the battery-system enclosure.

In one or more implementations, the battery-system enclosure further includes a plurality of cooling fans configured to blow fresh air into the compartments of the battery-system enclosure.

Yet another aspect of the subject technology is directed to a method including providing a battery pack for supplying a first DC voltage to a traction motor of an EV, and electrically coupling the battery pack to an output of one or more electrical machines to generate a second DC voltage for keeping the battery pack fully charged. The method further includes mechanically coupling an ICE to the one or more electrical machines, and coupling a fuel tank including a liquid fuel and positioned inside the EV to the ICE.

In one or more implementations, the battery pack, the ICE, and the one or more electrical machines are enclosed in a battery-system enclosure, wherein the battery-system enclosure further includes cooling fins, a plurality of exhaust fans and a plurality of cooling fans.

In some implementations, the method further comprises providing a battery-management system within the battery-system enclosure to manage an operation of the ICE to always keep the battery pack fully charged.

In some implementations, the word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” Pronouns in the masculine (e.g., his) include the feminine and neuter gender (e.g., her and its) and vice versa. The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public, regardless of whether such disclosure is explicitly recited in the above description. No clause element is to be construed under the provisions of 35 U.S.C. § 112, sixth paragraph, unless the element is expressly recited using the phrase “means for” or, in the case of a method clause, the element is recited using the phrase “step for.”

While this specification contains many specifics, these should not be construed as limitations on the scope of what may be described, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially described as such, one or more features from a described combination can in some cases be excised from the combination, and the described combination may be directed to a sub-combination or variation of a sub-combination.

The subject matter of this specification has been described in terms of particular aspects, but other aspects can be implemented and are within the scope of the following clauses. For example, while operations are depicted in the drawings in a particular order, this should not be understood as requiring that such operations be performed in the particular order shown or in sequential order, or that all illustrated operations be performed, to achieve desirable results. The actions recited in the clauses can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the clauses. In addition, in the detailed description, it can be seen that the description provides illustrative examples, and the various features are grouped together in various implementations for the purpose of streamlining the disclosure. The method of disclosure is not to be interpreted as reflecting an intention that the described subject matter requires more features than are expressly recited in each clause. Rather, as the clauses reflect, inventive subject matter lies in less than all features of a single disclosed configuration or operation. The clauses are hereby incorporated into the detailed description, with each clause standing on its own as a separately described subject matter.

Aspects of the subject matter described in this disclosure can be implemented to realize one or more of the following potential advantages. The described techniques may be implemented to support a range of benefits and significant advantages of the disclosed eye tracking system. It should be noted that the subject technology enables fabrication of a depth-sensing apparatus that is a fully solid-state device with small size, low power, and low cost.

As used herein, the phrase “at least one of” preceding a series of items, with the terms “and” or “or” to separate any of the items, modifies the list as a whole, rather than each member of the list (i.e., each item).

To the extent that the term “include,” “have,” or the like is used in the description or the claims, such term is intended to be inclusive in a manner similar to the term “comprise” as “comprise” is interpreted when employed as a transitional word in a claim.

A reference to an element in the singular is not intended to mean “one and only one” unless specifically stated, but rather “one or more.” All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. An apparatus, comprising:
a battery pack configured to provide power for an electrical vehicle (EV); and
a motor powered by a fuel supplied by a fuel tank and configured to provide mechanical power for one or more electrical machines,
wherein:
the one or more electrical machines are configured to generate a direct current (DC) voltage for keeping the battery pack fully charged; and
the battery pack, the motor and the one or more electrical machines are enclosed in a battery-system enclosure.

2. The apparatus of claim 1, wherein the motor comprises a single-stroke internal combustion engine (ICE).

3. The apparatus of claim 2, wherein the one or more electric machines comprise one or more alternators, and wherein the DC voltage is regulated to match a nominal voltage of the battery pack.

4. The apparatus of claim 2, wherein the fuel comprises a liquid fuel including one of, among others not named here, compressed natural gas (CNG), petrol, diesel, propane or hydrogen.

5. The apparatus of claim 2, wherein the fully charged battery pack comprises a level within a range of about 98 to 100 percent of a maximum allowable charge level associated with the battery pack.

6. The apparatus of claim 1, wherein the fuel tank is carried by the EV in a compartment inside the EV.

7. The apparatus of claim 1, wherein the battery-system enclosure further includes an internal heat shield arranged to shield a battery compartment including the battery pack from other components in the battery-system enclosure.

8. The apparatus of claim 1, wherein the battery-system enclosure further includes a battery-management system configured to control an operation of the motor to keep the battery pack fully charged.

9. The apparatus of claim 1, wherein the EV comprises one of a car, a truck, a boat, a ship, or an airplane.

10. The apparatus of claim 1, wherein the battery-system enclosure further includes cooling fins made of a heat conductive material.

11. The apparatus of claim 1, wherein the battery-system enclosure further includes a plurality of exhaust fans configured to remove hot air from compartments of the battery-system enclosure.

12. The apparatus of claim 1, wherein the battery-system enclosure further includes a plurality of cooling fans configured to blow fresh air into compartments of the battery-system enclosure.

13. An EV, comprising:
a battery system including:
a battery pack configured to provide power for a first electric motor;
a second motor configured to be powered by a fuel supplied by a fuel tank and to provide mechanical power for one or more electrical machines, wherein the one or more electrical machines are configured to generate a DC voltage for keeping the battery pack fully charged; and
a battery-management system configured to manage an operation of the second motor,
wherein the battery system is enclosed in a battery-system enclosure.

14. The EV of claim 13, wherein the battery-management system is configured to manage an operation of the second motor to keep the battery pack fully charged.

15. The EV of claim 13, wherein the first electric motor comprises a traction motor, and the second motor comprises a single-stroke ICE.

16. The EV of claim 13, wherein the fuel tank contains a liquid fuel comprising one of CNG, petrol, diesel, propane or hydrogen.

17. The EV of claim 13, wherein the battery-system enclosure further includes:
cooling fins made of a heat conductive material;
a plurality of exhaust fans configured to remove hot air from compartments of the battery-system enclosure;
a plurality of cooling fans configured to blow fresh air into the compartments of the battery-system enclosure; and
one or more vents configured to automatically open to allow filtered fresh air in the EVIG for cooling at a threshold speed, wherein the threshold speed is about 25 mile per hour (mph).

18. A method, comprising:
providing a battery pack for supplying a first DC voltage to a traction motor of an EV;
electrically coupling the battery pack to an output of one or more electrical machines to generate a second DC voltage for keeping the battery pack fully charged;
mechanically coupling an ICE to the one or more electrical machines; and
coupling a fuel tank including a liquid fuel and positioned inside the EV to the ICE.

19. The method of claim 18, wherein the battery pack, the ICE, and the one or more electrical machines are enclosed in a battery-system enclosure, wherein the battery-system enclosure further includes cooling fins, a plurality of exhaust fans and a plurality of cooling fans.

20. The method of claim 19, further comprising providing a battery-management system within the battery-system enclosure to manage an operation of the ICE to keep the battery pack fully charged.
